(19) United States
(12) Patent Application Publication
(10) Pub. No.: US 2026/0033144 A1
(43) Pub. Date: Jan. 29, 2026

(54) DISPLAY DEVICE AND METHOD FOR FABRICATION THEREOF

(71) Applicant: Samsung Display Co., LTD., Yongin-sI (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 19/079,365

(22) Filed: Mar. 13, 2025

(30) Foreign Application Priority Data
Jul. 29, 2024 (KR) 10-2024-0099943

(51) Int. Cl. H10K 59/122; H10K 59/12; H10K 59/80

(52) U.S. Cl. CPC H10K 59/122; H10K 59/1201; H10K 59/80522; H10K 59/873

(57) ABSTRACT

A display device includes: a substrate including an emission area and a non-emission area; a via layer on the substrate; an anode electrode overlapping the emission area and on the via layer; a pixel defining layer on the anode electrode and defining a first opening; and a bank structure on the pixel defining layer and defining a second opening, wherein the pixel defining layer and the bank structure surround a third opening in a portion overlapping the non-emission area, and the third opening does not overlap the anode electrode in the portion overlapping the non-emission area.

### CROSS-REFERENCE TO RELATED APPLICATION

The present application claims priority to and the benefit of Korean Patent Application No. 10-2024-0099943, filed on Jul. 29, 2024, in the Korean Intellectual Property Office, the entire disclosure of which is incorporated herein by reference.

### BACKGROUND

### 1. Field

Aspects of some embodiments of the present disclosure relate to a display device and a method for fabrication thereof.

### 2. Description of the Related Art

As the information society develops, consumer demand for display devices for displaying images has increased and diversified. For example, display devices have been applied to various electronic devices such as smartphones, digital cameras, laptop computers, navigation devices, and smart televisions. The display devices may include flat panel display devices such as liquid crystal display devices, field emission display devices, or organic light emitting display devices. Among such flat panel display devices, a light emitting display device may display images without a backlight unit providing light to a display panel because each of pixels of the display panel includes light emitting elements that may emit light by themselves.

Recently, the display devices have been applied to glasses-type devices for providing virtual reality and augmented reality. The display device is implemented in a very small size of 2 inches or less in order to be applied to the glasses-type device, but may desirably have a high pixel integration degree in order to be implemented with relatively high resolution. For example, the display device may have a high pixel integration degree of 400 pixels per inch (PPI) or more.

The above information disclosed in this Background section is only for enhancement of understanding of the background and therefore the information discussed in this Background section does not necessarily constitute prior art.

### SUMMARY

Aspects of some embodiments of the present disclosure include a display device that may be capable of forming light emitting layers or cathode electrodes separated from each other for each emission area without a separate fine metal mask, and a method for fabrication thereof.

Aspects of some embodiments of the present disclosure also include a display device in which a reliability defect caused by moisture is solved, and a method for fabrication thereof.

However, aspects of some embodiments of the present disclosure are not restricted to those set forth herein. The above and other aspects of embodiments according to the present disclosure will become more apparent to one of ordinary skill in the art to which the present disclosure pertains by referencing the detailed description of embodiments according to the present disclosure given below.

According to some embodiments of the present disclosure, a display device includes a substrate including an emission area and a non-emission area; a via layer positioned on the substrate; an anode electrode overlapping the emission area and positioned on the via layer; a pixel defining layer positioned on the anode electrode and defining a first opening; and a bank structure positioned on the pixel defining layer and defining a second opening, wherein the pixel defining layer and the bank structure are positioned to surround a third opening in a portion overlapping the non-emission area, and the third opening does not overlap the anode electrode in the portion overlapping the non-emission area.

According to some embodiments, a display device may further comprise a light emitting layer positioned on the anode electrode and in contact with the bank structure; a cathode electrode positioned on the light emitting layer and in contact with the bank structure; an element inorganic layer positioned on the cathode electrode; and an auxiliary electrode positioned on the element inorganic layer.

According to some embodiments, the bank structure may include a first bank layer and a second bank layer having different metal materials, and the second bank layer includes a tip protruding toward the first opening more than a first side surface of the first bank layer facing the emission area.

According to some embodiments, in a portion overlapping the emission area, the element inorganic layer may be in contact with and covers the first side surface of the first bank layer and the tip of the second bank layer.

According to some embodiments, in a portion overlapping the emission area, the second bank layer and the element inorganic layer may be spaced apart from each other in a direction perpendicular to the substrate with a cavity interposed therebetween.

According to some embodiments, a display device may further comprise an organic encapsulation layer positioned on the auxiliary electrode, wherein the organic encapsulation layer may fill the cavity.

According to some embodiments, in a plan view, the first opening may be entirely surrounded by the second opening.

According to some embodiments, the element inorganic layer may include a first element inorganic layer overlapping the emission area and an element inorganic pattern overlapping the non-emission area, and the first element inorganic layer and the element inorganic pattern are spaced apart from each other.

According to some embodiments, in a portion overlapping the third opening, the via layer may be exposed, and in the portion overlapping the third opening, the element inorganic pattern entirely covers the via layer.

According to some embodiments, the element inorganic pattern may be in contact with and covers a second side surface of the first bank layer facing the third opening.

According to some embodiments, in the portion overlapping the non-emission area, a side surface of the pixel defining layer facing the third opening may protrude toward the third opening more than a side surface of the anode electrode facing the third opening.

According to some embodiments, in the portion overlapping the non-emission area, the pixel defining layer and the side surface of the anode electrode facing the third opening may form an undercut.

According to some embodiments, the auxiliary electrode includes a first auxiliary electrode positioned on the first element inorganic layer and an auxiliary electrode pattern positioned on the element inorganic pattern, and the first auxiliary electrode and the auxiliary electrode pattern may be spaced apart from each other.

According to some embodiments, the cathode electrode may be electrically connected to the auxiliary electrode pattern through the bank structure.

According to some embodiments, the auxiliary electrode pattern may be in contact with the second bank layer.

According to some embodiments, a display device may further comprise an electrode pattern positioned on the via layer so as to overlap the third opening, wherein the electrode pattern includes the same material as the cathode electrode, and in the portion overlapping the non-emission area, the anode electrode may be spaced apart from the electrode pattern with a space interposed therebetween.

According to some embodiments of the present disclosure, a method for fabrication of a display device includes forming a substrate including an emission area and a non-emission area and forming a via layer on the substrate; entirely forming an anode electrode on the via layer and sequentially forming a pixel defining layer and a bank structure on the anode electrode; forming a first hole and a second hole by removing portions of the bank structure and the pixel defining layer, the first hole overlapping the emission area and the second hole overlapping the non-emission area; exposing the via layer overlapping the second hole by removing a portion of the anode electrode overlapping the second hole; removing moisture included in the via layer by performing a thermal process; and forming a light emitting layer, a cathode electrode, an inorganic element layer, and an auxiliary electrode on the anode electrode.

According to some embodiments, in the forming of the first hole, the bank structure includes a tip protruding toward the first hole.

According to some embodiments, in the forming of the light emitting layer and the cathode electrode, the light emitting layer and the cathode electrode may be formed by a deposition process and an etching process without a separate mask.

According to some embodiments of the present disclosure, an electronic device includes a display panel including a substrate including a display area including an emission area and a non-emission area and a non-display area surrounding an outer side of the display area, wherein the display panel further includes: a via layer positioned on the substrate; an anode electrode overlapping the emission area and positioned on the via layer; a pixel defining layer positioned on the anode electrode and defining a first opening; and a bank structure positioned on the pixel defining layer and defining a second opening, the pixel defining layer and the bank structure are positioned to surround a third opening in a portion overlapping the non-emission area, and the third opening does not overlap the anode electrode in the portion overlapping the non-emission area.

Further characteristics of some embodiments are described in more detail below and are illustrated in the drawings.

With a display device and a method for fabrication thereof according to some embodiments, it may be possible to form light emitting layers or cathode electrodes separated from each other for each emission area without a separate fine metal mask. In addition, with the display device and the method for fabrication thereof according to some embodiments, it may be possible to solve a reliability defect caused by moisture or other contaminants.

The characteristics of embodiments according to the present disclosure are not limited to the aforementioned characteristics, and various other characteristics are included in the present specification.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is a perspective view illustrating an electronic device according to some embodiments;

FIG. 2 is a perspective view illustrating a display device included in the electronic device according to some embodiments;

FIG. 3 is a schematic cross-sectional view of the display device of FIG. 2;

FIG. 4 is a plan view of a plurality of pixels positioned in a display area of FIG. 3;

FIG. 5 is a schematic cross-sectional view cut along the line I-I′ of FIG. 4;

FIG. 6 is an enlarged cross-sectional view of a display element layer overlapping a first emission area in FIG. 5;

FIG. 7 is an enlarged cross-sectional view of the display element layer overlapping a non-emission area positioned between the first emission area and a second emission area in FIG. 6.

FIG. 8 is a plan view illustrating an arrangement relationship of a via layer, an anode electrode, and a bank structure in FIG. 5; and

FIGS. 9 to 22 are schematic cross-sectional views illustrating aspects of a method for fabrication of the display element layer illustrated in FIG. 5.

FIG. 23 is a block diagram of an electronic device according to one embodiment of the present disclosure.

FIG. 24 is a schematic diagram of an electronic device according to various embodiments of the present disclosure.

### DETAILED DESCRIPTION

Aspects of some embodiments of the present disclosure will now be described more fully hereinafter with reference to the accompanying drawings, in which some embodiments of the disclosure are shown. The disclosure may, however, be embodied in different forms and should not be construed as limited to the embodiments set forth herein. Rather, these embodiments are provided so that this disclosure will be more thorough and more complete, and will more fully convey the scope of embodiments according to the present disclosure to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the disclosure. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

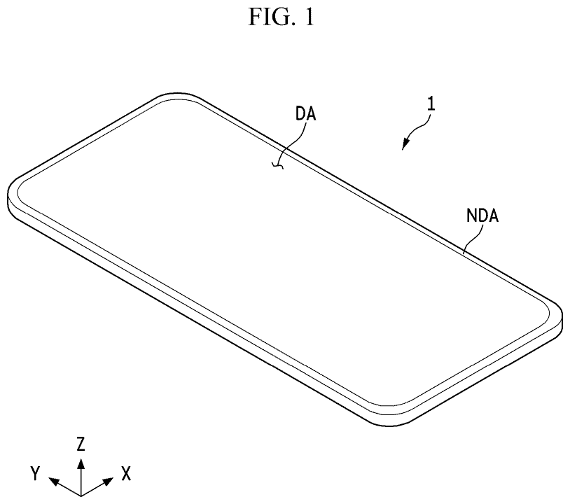

FIG. 1 is a schematic perspective view of an electronic device 1 according to some embodiments.

Referring to FIG. 1, the electronic device 1 displays a moving image (e.g., video images) or a still image (e.g., static images). As an example, the display device 1 may include portable electronic devices such as mobile phones, smartphones, smart watches, watch phones, mobile communication terminals, electronic notebooks, electronic books, portable multimedia players (PMPs), navigation devices, ultra mobile personal computers (UMPCs), and tablet PCs. Alternatively, the display device 1 may include televisions, laptop computers, monitors, billboards, or Internet of Things (IOT) devices.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a transverse direction in the drawings, the second direction (Y-axis direction) refers to a longitudinal direction in the drawings, and the third direction (Z-axis direction) refers to an upward and downward direction (i.e., a thickness direction) in the drawings. In the following specification, unless otherwise specified, the term “direction” may refer to both directions toward both sides extending along the direction. In addition, when both “directions” extending to both sides need to be distinguished from each other, one side will be referred to as “one side in the direction” and the other side will be referred to as “the other side in the direction”. In FIG. 1, a direction to which an arrow indicating a direction is directed will be referred to as one side, and a direction opposite to such a direction will be referred to as the other side.

Hereinafter, for convenience of explanation, in referring to surfaces of the electronic device 1 or respective members constituting the electronic device 1, one surface facing one side in a direction in which an image is displayed, that is, the third direction (Z-axis direction) will be referred to as an upper surface, and a surface opposite to the one surface will be referred to as the other surface. However, the present disclosure is not limited thereto, and the one surface and the other surface of the member may be referred to as a front surface and a rear surface, respectively, or be referred to as a first surface and a second surface, respectively. In addition, in describing relative positions of the respective members of the electronic device 1, one side in the third direction (Z-axis direction) may be referred to as an upper portion and the other side in the third direction (Z-axis direction) may be referred to as a lower portion.

A shape of the electronic device 1 may be variously modified. For example, the electronic device 1 may have a shape such as a rectangular shape with a width greater than a length, a rectangular shape with a length greater than a width, a square shape, a quadrangular shape with rounded corners (vertices), other polygonal or irregular shapes, or a circular shape.

The electronic device 1 may include a display area DA and a non-display area NDA. The display area DA is an area where a screen or images may be displayed, and the non-display area NDA is an area where the screen is (or images are) not displayed. The display area DA may also be referred to as an active area, and the non-display area NDA may also be referred to as a non-active area. The display area DA may occupy the center (or substantially the center) of the electronic device 1.

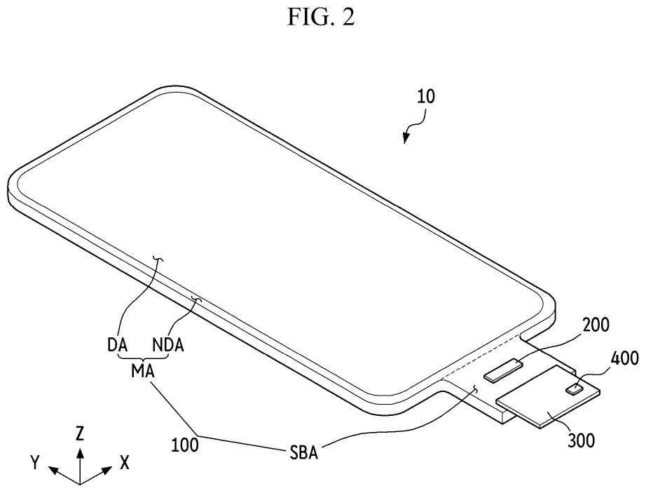

FIG. 2 is a perspective view illustrating a display device 10 included in the electronic device 1 according to some embodiments.

Referring to FIG. 2, the electronic device 1 according to some embodiments may include a display device 10. The display device 10 may provide a screen (e.g., display images) displayed on the electronic device 1. Examples of the display device 10 may include an inorganic light emitting diode display device, an organic light emitting display device, a quantum dot light emitting display device, a plasma display panel, a field emission display, and the like. Hereinafter, a case where an organic light emitting diode display device is applied as an example of the display device will be described by way of example, but embodiments according to the present disclosure are not limited thereto, and the same technical spirit may be applied to other display devices if applicable.

The display device 10 may have a shape similar to that of the electronic device 1 in a plan view. For example, the display device 10 may have a rectangular shape, in a plan view, having short sides in the first direction (X-axis direction) and long sides in the second direction (Y-axis direction). A corner where the short side in the first direction (X-axis direction) and the long side in the second direction (Y-axis direction) meet may be rounded with a curvature, but embodiments according to the present disclosure are not limited thereto, and may also be right-angled. The shape of the display device 10 in a plan view is not limited to the rectangular shape, and may be a shape similar to other polygonal shapes, a circular shape, or an elliptical shape. In the present disclosure, the phrase “in a plan view” refers to a view from a direction perpendicular or normal with respect to a display surface of the display device 10 or a plane defined by the first direction and the second direction.

The display device 10 may include a display panel 100, a display driver 200, and a circuit board 300.

The display panel 100 may include a main area MA and a sub-area SBA. The main area MA may include a display area DA including pixels displaying images and a non-display area NDA positioned around (e.g., in a periphery or outside a footprint of) the display area DA at which images are not displayed.

The display area DA may emit light from a plurality of emission areas or a plurality of openings to be described later. For example, the display panel 100 may include pixel circuits including switching elements, a pixel defining layer defining the emission areas or the openings, and self-light emitting elements. For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto. It has been illustrated in the drawings that the self-light emitting element is an organic light emitting diode.

The non-display area NDA may be an area outside the display area DA. The non-display area NDA may be defined as an edge area of the main area MA of the display panel 100.

The sub-area SBA may be an area extending from one side of the main area MA. The sub-area SBA may include a flexible material that may be bent, folded, and rolled without damaging the display device 10. For example, when the sub-area SBA is bent, the sub-area SBA may overlap the main area MA in the thickness direction (e.g., the third direction (Z-axis direction)). The sub-area SBA may include the display driver 200 and pad portions connected to the circuit board 300. According to some embodiments, the sub-area SBA may be omitted, and the display driver 200 and the pad portions may be positioned in the non-display area NDA.

The display driver 200 may output signals and voltages for driving the display panel 100. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be positioned in the sub-area SBA, and may overlap the main area MA in the thickness direction by bending of the sub-area SBA. As another example, the display driver 200 may be mounted on the circuit board 300.

The circuit board 300 may be attached onto the pad portions of the display panel 100 using an anisotropic conductive film (ACF). The circuit board 300 may be a flexible printed circuit board, a printed circuit board, or a flexible film such as a chip on film.

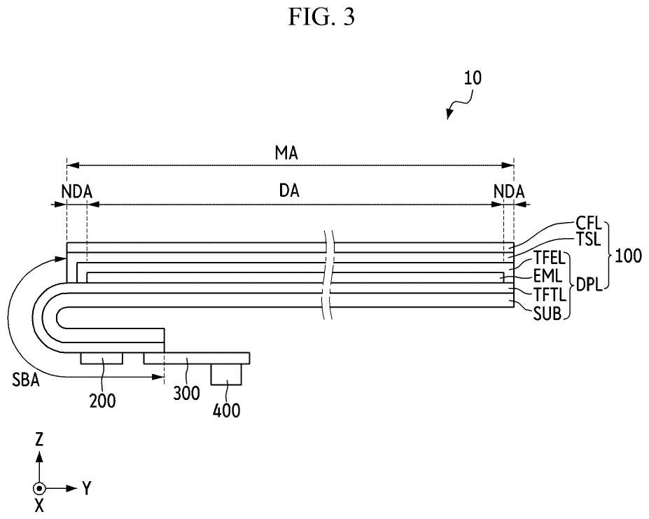

FIG. 3 is a schematic cross-sectional view of the display device of FIG. 2.

Referring to FIG. 3, the display panel 100 may include a display layer DPL, a touch sensor layer TSL, and a color filter layer CFL. The display layer DPL may include a substrate SUB, a thin film transistor layer TFTL, a display element layer EML, and a thin film encapsulation layer TFEL.

The substrate SUB may be a base substrate or a base member. The substrate SUB may be a flexible substrate that may be bent, folded, and rolled. For example, the substrate SUB may include a polymer resin such as polyimide (PI), but is not limited thereto. According to some embodiments, the substrate SUB may include a glass material or a metal material.

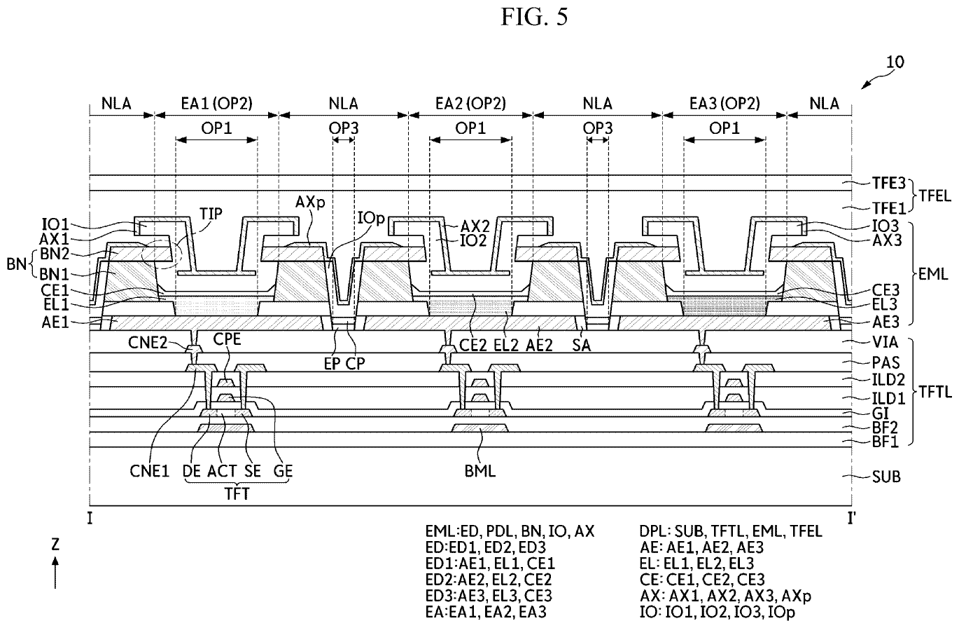

The thin film transistor layer TFTL may be positioned on the substrate SUB. The thin film transistor layer TFTL may be positioned in a portion overlapping the display area DA, the non-display area NDA, and the sub-area SBA. The thin film transistor layer TFTL may include a plurality of thin film transistors TFT (see FIG. 5).

The display element layer EML may be positioned on the thin film transistor layer TFTL. The display element layer EML may be positioned in a portion overlapping the display area DA. The display element layer EML may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto.

The thin film encapsulation layer TFEL may be positioned on the display element layer EML. The thin film encapsulation layer TFEL may be positioned in a portion overlapping the display area DA and the non-display area NDA. The thin film encapsulation layer TFEL may cover an upper surface and side surfaces of the display element layer EML, and may protect the display element layer EML from external oxygen and moisture. The thin film encapsulation layer TFEL may include at least one inorganic film and at least one organic film for encapsulating the display element layer EML.

The touch sensor layer TSL may be positioned on the thin film encapsulation layer TFEL. The touch sensor layer TSL may be positioned in a portion overlapping the display area DA and the non-display area NDA. The touch sensor layer TSL may sense a user's touch in a mutual capacitance manner or a self-capacitance manner.

The color filter layer CFL may be positioned on the touch sensor layer TSL. The color filter layer CFL may be positioned in a portion overlapping the display area DA and the non-display area NDA. The color filter layer CFL may absorb some of light introduced from the outside of the display device 10 to relatively reduce reflected light by external light. Accordingly, the color filter layer CFL may prevent or reduce distortion of colors due to external light reflection.

Because the color filter layer CFL is directly located on the touch sensor layer TSL, the display device 10 may not require a separate substrate for the color filter layer CFL. Accordingly, a thickness of the display device 10 may be relatively small. The color filter layer CFL may also be omitted according to embodiments.

As illustrated in FIG. 3, a portion of the display panel 100 overlapping the sub-area SBA may be bent. When a portion of the display panel 100 is bent, the display driver 200, the circuit board 300, and a touch driver 400 may overlap the main area MA in the third direction (Z-axis direction).

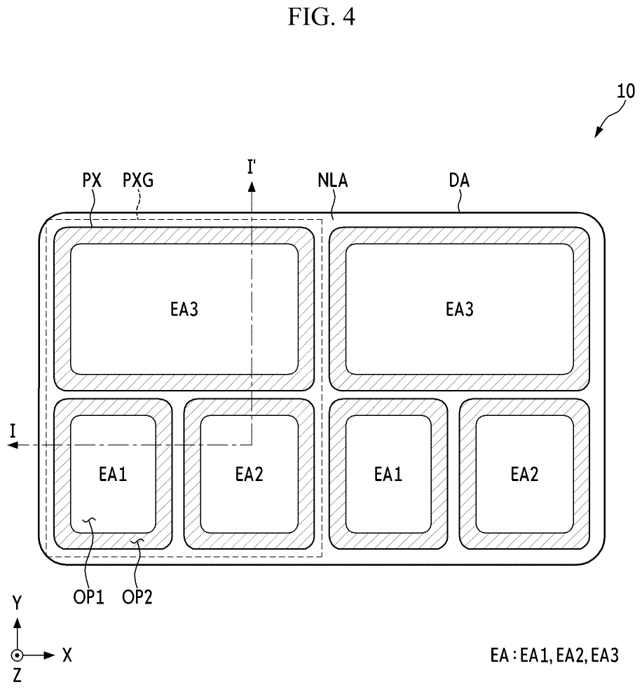

FIG. 4 is a plan view of a plurality of pixels positioned in a display area of FIG. 3.

Referring to FIG. 4, the display area DA according to some embodiments may include an emission area EA and a non-emission area NLA. The emission area EA may include a first emission area EA1, a second emission area EA2, and a third emission area EA3 spaced apart from each other, and the non-emission area NLA may be positioned to surround each of the first emission area EA1, the second emission area EA2, and the third emission area EA3. The non-emission area NLA may assist in preventing or reducing light of respective colors emitted from the first emission area EA1, the second emission area EA2, and the third emission area EA3 from being mixed with each other.

The first emission area EA1, the second emission area EA2, and the third emission area EA3 may emit light of different colors, respectively. Colors of the light emitted from the first emission area EA1, the second emission area EA2, and the third emission area EA3 may be different from each other depending on a type of a light emitting element ED (see FIG. 5) to be described in more detail below. As an example, the first emission area EA1 may emit red light, which is light of a first color, the second emission area EA2 may emit green light, which is light of a second color, and the third emission area EA3 may emit blue light, which is light of a third color, but embodiments according to the present disclosure are not limited thereto. Sizes and shapes of the first emission area EA1, the second emission area EA2, and the third emission area EA3 may be freely adjusted according to required characteristics.

The emission area EA may be defined by a first opening OP1 and a second opening OP2. In a plan view, the second opening OP2 may completely surround the first opening OP1, and may be completely surrounded by the non-emission area NLA. The first opening OP1 and the second opening OP2 will be described later.

According to some embodiments, a pixel PX having at least one first emission area EA1, a pixel PX having at least one second emission area EA2, and a pixel PX having at least one third emission area EA3, which are located adjacent to each other, may constitute one pixel group PXG. The pixel group PXG may be a minimum unit emitting white light. However, types and/or the numbers of first emission areas EA1, second emission areas EA2, and third emission areas EA3 constituting the pixel group PXG may be changed according to embodiments.

FIG. 5 is a schematic cross-sectional view cut along the line I-I′ of FIG. 4. FIG. 5 illustrates a schematic cross section of the display layer overlapping the display area of the display device.

Referring to FIG. 5, the thin film transistor layer TFTL may be positioned on the substrate SUB. The thin film transistor layer TFTL may include a first buffer layer BF1, a bottom metal layer BML, a second buffer layer BF2, thin film transistors TFT, a gate insulating layer GI, a first insulating layer ILD1, capacitor electrodes CPE, a second insulating layer ILD2, first connection electrodes CNE1, a passivation layer PAS, second connection electrodes CNE2, and a via layer VIA.

The first buffer layer BF1 may be positioned on the substrate SUB. The first buffer layer BF1 may include an inorganic film capable of preventing or reducing permeation of contaminants such as air or moisture. For example, the first buffer layer BF1 may include a plurality of inorganic films that are alternately stacked.

The bottom metal layer BML may be positioned on the first buffer layer BF1. For example, the bottom metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second buffer layer BF2 may cover the first buffer layer BF1 and the bottom metal layer BML. The second buffer layer BF2 may include an inorganic film capable of preventing or reducing permeation of contaminants such as air or moisture. For example, the second buffer layer BF2 may include a plurality of inorganic films that are alternately stacked.

The thin film transistor TFT may be located on the second buffer layer BF2, and may constitute a pixel circuit connected to each of the plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be positioned on the second buffer layer BF2. The active layer ACT may overlap the gate electrode GE in the third direction (Z-axis direction), and may be insulated from the gate electrode GE by the gate insulating layer GI. The source electrode SE and the drain electrode DE may be formed by making a material of the active layer ACT in portions of the active layer ACT conductors.

The gate electrode GE may be positioned on the gate insulating layer GI. The gate electrode GE may overlap the active layer ACT with the gate insulating layer GI interposed therebetween.

The gate insulating layer GI may be positioned on the active layer ACT. The gate insulating layer GI may cover the active layer ACT and the second buffer layer BF2, and may insulate the active layer ACT and the gate electrode GE from each other. The gate insulating layer GI may include contact holes through which the first connection electrodes CNE1 penetrate.

The first insulating layer ILD1 may cover the gate electrode GE and the gate insulating layer GI. The first insulating layer ILD1 may include contact holes through which the first connection electrodes CNE1 penetrate. The contact holes of the first insulating layer ILD1 may be connected to the contact holes of the gate insulating layer GI and contact holes of the second insulating layer ILD2.

The capacitor electrodes CPE may be positioned on the first insulating layer ILD1. The capacitor electrode CPE may overlap the gate electrode GE in the third direction (Z-axis direction). The capacitor electrode CPE and the gate electrode GE may form capacitance.

The second insulating layer ILD2 may cover the capacitor electrodes CPE and the first insulating layer ILD1. The second insulating layer ILD2 may include contact holes through which the first connection electrodes CNE1 penetrate. The contact holes of the second insulating layer ILD2 may be connected to the contact holes of the first insulating layer ILD1 and the contact holes of the gate insulating layer GI.

The first connection electrodes CNE1 may be positioned on the second insulating layer ILD2. The first connection electrode CNE1 may electrically connect the drain electrode DE of the thin film transistor TFT and the second connection electrode CNE2 to each other. The first connection electrode CNE1 may be inserted into the contact holes formed in the first insulating layer ILD1, the second insulating layer ILD2, and the gate insulating layer GI to be in contact with the drain electrode DE of the thin film transistor TFT.

The passivation layer PAS may cover the first connection electrodes CNE1 and the second insulating layer ILD2. The passivation layer PAS may planarize an underlying structure. The passivation layer PAS may include contact holes through which the second connection electrodes CNE2 penetrate.

The passivation layer PAS may include an organic insulating material. As an example, the passivation layer PAS may include an acrylic resin, polyimide, polyamide, benzocyclobutene, a phenol resin, or the like.

The second connection electrodes CNE2 may be positioned on the passivation layer PAS. The second connection electrode CNE2 may be inserted into the contact hole formed in the passivation layer PAS to be in contact with the first connection electrode CNE1. The second connection electrode CNE2 may electrically connect the first connection electrode CNE1 and an anode electrode AE to each other.

The via layer VIA may cover the second connection electrodes CNE2 and the passivation layer PAS. The via layer VIA may include contact holes through which the anode electrodes AE penetrate.

The via layer VIA may include an organic material. As an example, the via layer VIA may include an acrylic resin, polyimide, polyamide, benzocyclobutene, a phenol resin, or the like.

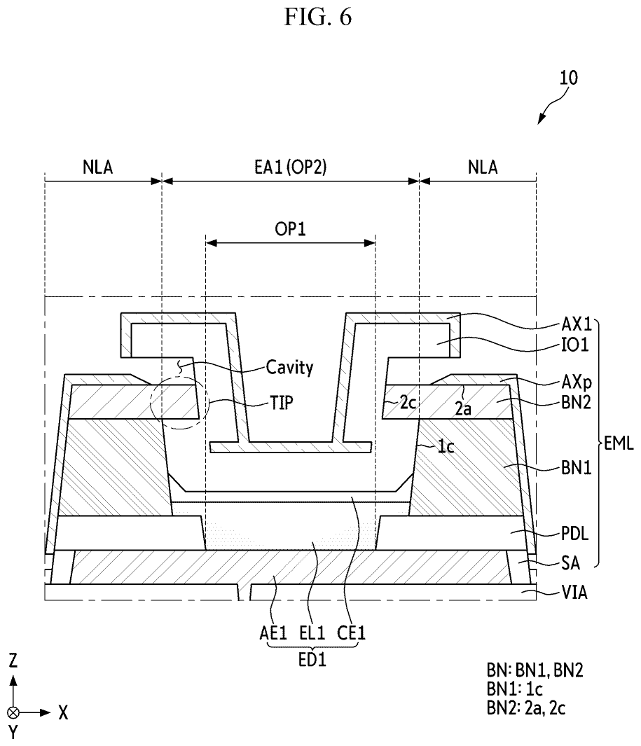

FIG. 6 is an enlarged cross-sectional view of a display element layer overlapping a first emission area in FIG. 5.

Referring to FIG. 6 in addition to FIG. 5, the display element layer EML may be positioned on the thin film transistor layer TFTL. The display element layer EML may include a light emitting element ED, a pixel defining layer PDL, a bank structure BN, an element inorganic layer IO, and an auxiliary electrode AX.

The light emitting element ED according to some embodiments may include a first light emitting element ED1 located in the first emission area EA1, a second light emitting element ED2 located in the second emission area EA2, and a third light emitting element ED3 located in the third emission area EA3.

The first light emitting element ED1 may include a first anode electrode AE1, a first light emitting layer EL1, and a first cathode electrode CE1, the second light emitting element ED2 may include a second anode electrode AE2, a second light emitting layer EL2, and a second cathode electrode CE2, and the third light emitting element ED3 may include a third anode electrode AE3, a third light emitting layer EL3, and a third cathode electrode CE3.

The first light emitting element ED1, the second light emitting element ED2, and the third light emitting element ED3 may emit light of different colors depending on materials of light emitting layers EL respectively included in the first light emitting element ED1, the second light emitting element ED2, and the third light emitting element ED3. For example, the first light emitting element ED1 may emit red light, the second light emitting element ED2 may emit green light, and the third light emitting element ED4 may emit blue light.

The anode electrode AE according to some embodiments may be positioned on the via layer VIA. The anode electrode AE may be positioned to overlap the emission area EA and the non-emission area NLA. The anode electrode AE may be in contact with the second connection electrode CNE2 through the contact hole penetrating through the via layer VIA, and may be electrically connected to the drain electrode DE of the thin film transistor TFT through the first connection electrode CNE1.

The anode electrode AE may include a transparent electrode material and/or a conductive metal material, and may have a single-layer or multilayer structure. As an example, the anode electrode AE may include one or more of silver (Ag), copper (Cu), aluminum (Al), nickel (Ni), lanthanum (La), titanium (Ti), and titanium nitride (TiN). Alternatively, the anode electrode AE may include one or more of indium tin oxide (ITO), indium zinc oxide (IZO), and indium tin zinc oxide (ITZO). According to some embodiments, the anode electrode AE may have a multilayer structure including a metal material layer and a transparent electrode material layer.

The anode electrode AE may include the first anode electrode AE1 positioned in the first emission area EA1, the second anode electrode AE2 positioned in the second emission area EA2, and the third anode electrode AE3 positioned in the third emission area EA3. The first anode electrode AE1, the second anode electrode AE2, and the third anode electrode AE3 may be positioned to be spaced apart from each other on the via layer VIA.

Spaces SA may be positioned on both sides of the anode electrode AE in the first direction (X-axis direction). In other words, the anode electrode AE may be surrounded by the spaces SA. For example, a side surface a1 of the anode electrode AE (e.g., the first anode electrode AE1) facing the non-emission area NLA may be entirely covered by the space SA. The space SA may have the same meaning as an empty space, that is, a cavity.

The pixel defining layer PDL according to some embodiments may be positioned on the anode electrode AE in a portion overlapping the non-emission area NLA. The pixel defining layer PDL may also be positioned in a portion overlapping the emission area EA.

The pixel defining layer PDL may not be in contact with the via layer VIA. In other words, the pixel defining layer PDL may be spaced apart from the via layer VIA in the third direction (Z-axis direction) with the anode electrode AE interposed therebetween.

The pixel defining layer PDL may define a first opening OP1. The pixel defining layer PDL may expose a portion of the anode electrode AE in a portion that overlaps the first opening OP1, and may cover a portion of the anode electrode AE in a portion that does not overlap the first opening OP1.

The pixel defining layer PDL may include an inorganic insulating material. As an example, the pixel defining layer PDL may include any one of aluminum oxide, titanium oxide, tantalum oxide, hafnium oxide, zinc oxide, silicon oxide, silicon nitride, and silicon oxynitride.

The bank structure BN according to some embodiments may be positioned on the pixel defining layer PDL in a portion overlapping the non-emission area NLA. The bank structure BN may define a second opening OP2.

The bank structure BN may include a first bank layer BN1 and a second bank layer BN2 including different metal materials and structures and playing different roles.

The first bank layer BN1 according to some embodiments may be positioned on the pixel defining layer PDL. The first bank layer BN1 may include a metal having high electrical conductivity. As an example, the first bank layer BN1 may include aluminum (Al).

The first bank layer BN1 may serve to electrically connect the first cathode electrode CE1, the second cathode electrode CE2, and the third cathode electrode CE3 respectively positioned in the first emission area EA1, the second emission area EA2, and the third emission area EA3 to each other.

According to some embodiments, the first bank layer BN1 may include a first side surface 1c. The first side surface 1c may be one surface facing the first opening OP1, and may be positioned to be depressed more than the pixel defining layer PDL in a direction toward the non-emission area NLA, that is, toward one side in the first direction (X-axis direction). The light emitting layer EL and the cathode electrode CE may be in contact with the first side surface 1c of the first bank layer BN1. Detailed contents thereof will be described later.

The second bank layer BN2 according to some embodiments may be positioned on the first bank layer BN1. The second bank layer BN2 may include a material having an etch rate lower than that of the first bank layer BN1. As an example, the second bank layer BN2 may include titanium (Ti).

The second bank layer BN2 may include a tip TIP protruding toward the first opening OP1 more than the first side surface 1c of the first bank layer BN1. The second bank layer BN2 has a shape in which it protrudes toward the emission area EA more than the first side surface 1c of the first bank layer BN1, and accordingly, an undercut structure may be formed between the tip TIP of the second bank layer BN2 and the first side surface 1c of the first bank layer BN1. The tip TIP of the second bank layer BN2 may be formed due to different etch rates of the first bank layer BN1 and the second bank layer BN2. A fabricating process will be described in more detail later.

In general, in a high-resolution display device, an interval between a plurality of light emitting elements ED neighboring to each other may be narrow. Accordingly, it may be difficult to form the plurality of light emitting elements ED included in the high-resolution display device using a mask in a fabricating process.

In the display device 10 according to some embodiments, the second bank layer BN2 of the bank structure BN includes the tip TIP, and thus, it is possible to form the first light emitting element ED1, the second light emitting element ED2, and the third light emitting element ED3 respectively overlapping the first emission area EA1, the second emission area EA2, and the third emission area EA3 without a separate fine metal mask in a fabricating process. The fabricating process will be described later.

The light emitting layer EL according to some embodiments may be positioned on the anode electrode AE. The light emitting layer EL may be an organic light emitting layer made of an organic material, and may be formed on the anode electrode AE through a deposition process. When the thin film transistor TFT applies a voltage (e.g., a set or predetermined voltage) to the anode electrode AE and the cathode electrode CE receives a common voltage or a cathode voltage, holes and electrons may move to the light emitting layer EL through a hole transporting layer and an electron transporting layer, respectively, and may be combined with each other in the light emitting layer EL to emit light.

The light emitting layer EL may include the first light emitting layer EL1, the second light emitting layer EL2, and the third light emitting layer EL3 respectively located in the first emission area EA1, the second emission area EA2, and the third emission area EA. The first light emitting layer EL1 may be located on the first anode electrode AE1 in the first emission area EA1, the second light emitting layer EL2 may be located on the second anode electrode AE2 in the second emission area EA2, and the third light emitting layer EL3 may be located on the third anode electrode AE3 in the third emission area EA3.

The first light emitting layer EL1, the second light emitting layer EL2, and the third light emitting layer EL3 may emit light of different colors. As an example, the first light emitting layer EL1 may emit red light, the second light emitting layer EL2 may emit green light, and the third light emitting layer EL3 may emit blue light.

The light emitting layer EL may cover the pixel defining layer PDL in a portion overlapping the second opening OP2, and may be in contact with the first bank layer BN1. As an example, the light emitting layer EL (e.g., the first light emitting layer EL1) may be in contact with the first side surface 1c of the first bank layer BN1.

An organic pattern EP according to some embodiments may be positioned on the via layer VIA in a portion overlapping the non-emission area NLA. The organic pattern EP may include the same material as at least one of the first light emitting layer EL1, the second light emitting layer EL2, or the third light emitting layer EL3. The organic pattern EP will be described in more detail later.

The cathode electrode CE according to some embodiments may be positioned on the light emitting layer EL. The cathode electrode CE may include a transparent conductive material to emit the light generated from the light emitting layer EL. The cathode electrode CE may receive a common voltage or a low potential voltage.

The cathode electrode CE may include the first cathode electrode CE1, the second cathode electrode CE2, and the third cathode electrode CE3 respectively located in the first emission area EA1, the second emission area EA2, and the third emission area EA. The first cathode electrode CE1 may be located on the first light emitting layer EL1 in the first emission area EA1, the second cathode electrode CE2 may be located on the second light emitting layer EL2 in the second emission area EA2, and the third cathode electrode CE3 may be located on the third light emitting layer EL3 in the third emission area EA3. The first cathode electrode CE1, the second cathode electrode CE2, and the third cathode electrode CE3 may be spaced apart from each other with the bank structure BN interposed therebetween.

The cathode electrode CE may cover the light emitting layer EL in a portion overlapping the second opening OP2, and may be in contact with the first bank layer BN1. As an example, the cathode electrode CE (e.g., the first cathode electrode CE1) may be in contact with the first side surface 1c of the first bank layer BN1.

An electrode pattern CP according to some embodiments may be positioned on the organic pattern EP in a portion overlapping the non-emission area NLA. The electrode pattern CP may include the same material as the cathode electrode CE. The electrode pattern CP will be described later.

The element inorganic layer IO according to some embodiments may be positioned on the light emitting element ED. The element inorganic layer IO may prevent or reduce instances of contaminants such as oxygen or moisture permeating into the light emitting element ED by covering the light emitting element ED.

The element inorganic layer IO may include an inorganic insulating material. As an example, the element inorganic layer IO may include any one of silicon nitride, silicon oxide, and silicon oxynitride.

The element inorganic layer IO may include a first element inorganic layer IO1, a second element inorganic layer IO2, a third element inorganic layer IO3, and an element inorganic pattern IOp. The first element inorganic layer IO1 may be located on the first light emitting element ED1 in the first emission area EA1, the second element inorganic layer IO2 may be located on the second light emitting element ED2 in the second emission area EA2, and the third element inorganic layer IO3 may be located on the third light emitting element ED3 in the third emission area EA3. The first element inorganic layer IO1, the second element inorganic layer IO2, and the third element inorganic layer IO3 may be spaced apart from each other in the first direction (X-axis direction) in a portion overlapping the non-emission area NLA.

The element inorganic layer IO (e.g., the first element inorganic layer IO1) may be in entire contact with and entirely cover the light emitting element ED in a portion overlapping the first opening OP1, and may be in contact with and cover the first side surface 1c of the first bank layer BN1 and a first side surface 2c of the second bank layer BN2 in a portion overlapping the second opening OP2. In other words, the element inorganic layer IO (e.g., the first element inorganic layer IO1) may cover a portion of the tip TIP of the second bank layer BN2, and may also be in entire contact with and entirely cover an undercut portion formed by the first side surface 1c of the first bank layer BN1 and the tip TIP of the second bank layer BN2.

The element inorganic layer IO (e.g., the first element inorganic layer IO1) may be spaced apart from an upper surface 2a of the second bank layer BN2 in a portion overlapping the second opening OP2 and the non-emission area NLA. In other words, the element inorganic layer IO (e.g., the first element inorganic layer IO1) may be spaced apart from the upper surface 2a of the second bank layer BN2 in the third direction (Z-axis direction) with a cavity Cavity interposed therebetween in the portion overlapping the second opening OP2 and the non-emission area NLA.

The cavity Cavity formed between the element inorganic layer IO and the second bank layer BN2 may be formed by temporarily forming and then removing the organic pattern EP and the electrode pattern CP in a fabricating process of the display device 10. The fabricating process will be described later.

The element inorganic pattern IOp will be described later.

The auxiliary electrode AX according to some embodiments may be positioned on the element inorganic layer IO. The auxiliary electrode AX may be in entire contact with and entirely cover the element inorganic layer IO in a portion overlapping the emission area EA and the non-emission area NLA.

The auxiliary electrode AX may include a first auxiliary electrode AX1, a second auxiliary electrode AX2, a third auxiliary electrode AX3, and an auxiliary electrode pattern AXp. The first auxiliary electrode AX1 may be located on the first element inorganic layer IO1 in the first emission area EA1, the second auxiliary electrode AX2 may be located on the second element inorganic layer IO2 in the second emission area EA2, and the third auxiliary electrode AX3 may be located on the third element inorganic layer IO3 in the third emission area EA3. The first auxiliary electrode AX1, the second auxiliary electrode AX2, the third auxiliary electrode AX3 may be spaced apart from each other in the first direction (X-axis direction) in a portion overlapping the non-emission area NLA.

The auxiliary electrode pattern AXp will be described in more detail later.

The thin film encapsulation layer TFEL according to some embodiments may be positioned on the display element layer EML. The thin film encapsulation layer TFEL may include an organic encapsulation layer TFE1 and an inorganic encapsulation layer TFE3.

The organic encapsulation layer TFE1 according to some embodiments may be positioned on the auxiliary electrode AX. As an example, the organic encapsulation layer TFE1 may be in entire contact with and entirely cover the first auxiliary electrode AX1, the second auxiliary electrode AX2, the third auxiliary electrode AX3, and the auxiliary electrode pattern AXp.

The organic encapsulation layer TFE1 may planarize a step formed along a profile of an underlying structure. In addition, the organic encapsulation layer TFE1 may fill the cavity Cavity formed between the second bank layer BN2 and the element inorganic layer IO in a portion overlapping the emission area EA.

The organic encapsulation layer TFE1 may include a polymer-based material. As an example, the organic encapsulation layer TFE1 may include an acrylic resin, a silicone resin, an epoxy-based resin, a silicone acrylic resin, polyimide, polyethylene, or the like.

The inorganic encapsulation layer TFE3 according to some embodiments may be positioned on the organic encapsulation layer TFE1. The inorganic encapsulation layer TFE3 may protect an underlying structure so that moisture and oxygen do not permeate into the underlying structure.

The inorganic encapsulation layer TFE3 may include an inorganic insulating material. As an example, the inorganic encapsulation layer TFE3 may include any one of silicon nitride, silicon oxide, and silicon oxynitride.

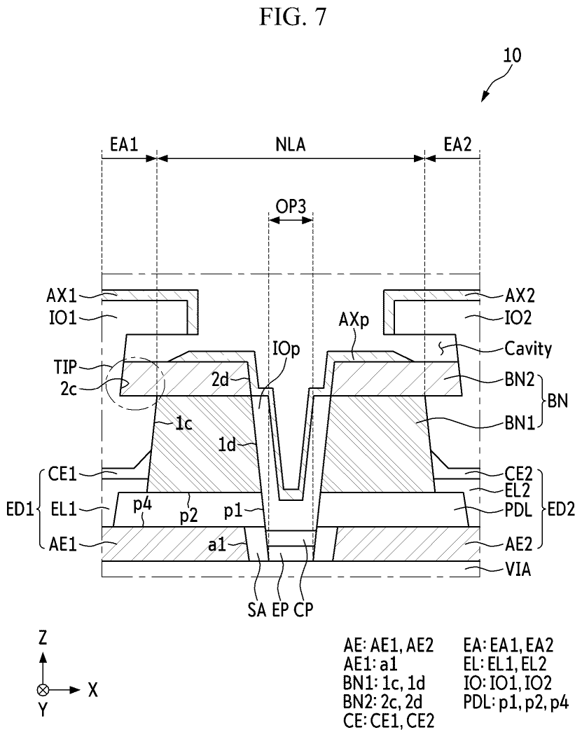

FIG. 7 is an enlarged cross-sectional view of the display element layer overlapping a non-emission area positioned between the first emission area and a second emission area in FIG. 6.

Referring to FIG. 7 in addition to FIGS. 5 and 6, in a portion overlapping the non-emission area NLA, the via layer VIA may be exposed without being covered by the anode electrode AE in a portion overlapping a third opening OP3.

In other words, in the portion overlapping the non-emission area NLA, the respective anode electrodes AE may be spaced apart from each other with the third opening OP3 interposed therebetween. As an example, the first anode electrode AE1 and the second anode electrode AE2 may be spaced apart from each other with the third opening OP3 interposed therebetween, and the second anode electrode AE2 and the third anode electrode AE3 may also be spaced apart from each other with the third opening OP3 interposed therebetween. In other words, in the portion overlapping the non-emission area NLA, the respective anode electrodes AE may not overlap the third opening OP3.

In the display device 10 according to some embodiments, by removing the anode electrode AE overlapping the third opening OP3 in the fabricating process, it is possible to temporarily expose the via layer VIA, and it is possible to outgas moisture included in the via layer through a subsequent thermal process. The fabricating process will be described in more detail later.

In the portion overlapping the non-emission area NLA, the organic pattern EP and the electrode pattern CP may be positioned on the via layer VIA so as to overlap the third opening OP3. In the portion overlapping the third opening OP3, the organic pattern EP and the electrode pattern CP may entirely cover the via layer VIA.

The organic pattern EP may include the same material as at least one of the first light emitting layer EL1, the second light emitting layer EL2, or the third light emitting layer EL3, and may be spaced apart from the light emitting layer EL. As described above, the light emitting layer EL according to some embodiments may be formed by deposition and etching processes. Accordingly, the organic pattern EP may be formed by depositing a material forming the light emitting layer EL in the portion overlapping the third opening OP3 as well as the portion overlapping the emission area EA in the fabricating process. In other words, the organic pattern EP may indicate that a separate fine metal mask is not used in a process of forming the light emitting layer EL in the fabricating process of the display device 10.

The electrode pattern CP may include the same material as the cathode electrode CE, and may be spaced apart from the cathode electrode CE. As described above, the cathode electrode CE according to some embodiments may be formed by deposition and etching processes rather than a mask process. Accordingly, the electrode pattern CP may be formed by depositing a material forming the cathode electrode CE in the portion overlapping the third opening OP3 as well as the portion overlapping the emission area EA in the fabricating process. In other words, the electrode pattern CP may indicate that a separate fine metal mask is not used in a process of forming the cathode electrode CE in the fabricating process of the display device 10.

An arrangement relationship of the organic pattern EP and the electrode pattern CP may be the same as an arrangement relationship of the light emitting layer EL and the cathode electrode CE. That is, the electrode pattern CP may entirely cover the organic pattern EP.

In the portion overlapping the non-emission area NLA, the first anode electrode AE1 and the second anode electrode AE2 may be spaced apart from each other with the organic pattern EP and the electrode pattern CP interposed therebetween, and the second anode electrode AE2 and the third anode electrode AE3 may be spaced apart from each other with the organic pattern EP and the electrode pattern CP interposed therebetween.

In the portion overlapping the non-emission area NLA, each of the first anode electrode AE1, the second anode electrode AE2, and the third anode electrode AE3 may be surrounded by the space SA. In a cross section, each of the first anode electrode AE1, the second anode electrode AE2, and the third anode electrode AE3 and the organic pattern EP and the electrode pattern CP may be spaced apart from each other with the space SA interposed therebetween. The space SA may have the same meaning as an empty space or a cavity. The space SA may be formed by removing a portion of the anode electrode AE by an etching process in the fabricating process. The fabricating process will be described later.

In the portion overlapping the non-emission area NLA, the pixel defining layer PDL may be positioned to surround the third opening OP3. In other words, the pixel defining layer PDL positioned on the first anode electrode AE1 and the pixel defining layer PDL positioned on the second anode electrode AE2 may be spaced apart from each other with the third opening OP3 interposed therebetween, and the pixel defining layer PDL positioned on the second anode electrode AE2 and the pixel defining layer PDL positioned on the third anode electrode AE3 may be spaced apart from each other with the third opening OP3 interposed therebetween.

According to some embodiments, a side surface p1 of the pixel defining layer PDL facing the non-emission area NLA may be covered by the element inorganic pattern IOp.

According to some embodiments, the side surface p1 of the pixel defining layer PDL may protrude more than the side surface a1 of the first anode electrode AE1 in a direction toward the third opening OP3. Accordingly, in the portion overlapping the non-emission area NLA, an undercut may be formed between the side surface a1 of the first anode electrode AE1 and the pixel defining layer PDL. An undercut shape between the side surface a1 of the first anode electrode AE1 and the pixel defining layer PDL may be formed because the anode electrode AE and the pixel defining layer PDL have different etch rates in the fabricating process. The fabricating process will be described later.

In the portion overlapping the non-emission area NLA, an upper surface p2 and a lower surface p4 of the pixel defining layer PDL may be flat surfaces.

In the fabricating process of the display device 10, the anode electrode AE and the pixel defining layer PDL may be entirely formed on the via layer VIA, and then be partially removed by a subsequent process. For this reason, the anode electrode AE and the pixel defining layer PDL included in the display device 10 may not include a step, and may have a flat shape.

In the display device 10 according to some embodiments, the anode electrode AE and the pixel defining layer PDL are formed in the flat shape, and accordingly, the pixel defining layer PDL may have excellent step coverage characteristics. For this reason, the display device 10 may solve a seam defect (e.g., a void defect) of the pixel defining layer PDL. Accordingly, the display device 10 according to some embodiments may solve a leakage current defect due to the contact between the anode electrode AE and the cathode electrode CE.

In the portion overlapping the non-emission area NLA, the first bank layer BN1 may be positioned to surround the third opening OP3. In other words, the first bank layer BN1 positioned on the first anode electrode AE1 and the first bank layer BN1 positioned on the second anode electrode AE2 may be spaced apart from each other with the third opening OP3 interposed therebetween. In addition, the first bank layer BN1 positioned on the second anode electrode AE2 and the first bank layer BN1 positioned on the third anode electrode AE3 may be spaced apart from each other with the third opening OP3 interposed therebetween.

According to some embodiments, a second side surface 1d of the first bank layer BN1 facing the non-emission area NLA may be covered by the element inorganic pattern IOp.

In the portion overlapping the non-emission area NLA, the second bank layer BN2 may be positioned to surround the third opening OP3. In other words, the second bank layer BN2 positioned on the first anode electrode AE1 and the second bank layer BN2 positioned on the second anode electrode AE2 may be spaced apart from each other with the third opening OP3 interposed therebetween, and the second bank layer BN2 positioned on the second anode electrode AE2 and the second bank layer BN2 positioned on the third anode electrode AE3 may be spaced apart from each other with the third opening OP3 interposed therebetween.

According to some embodiments, a second side surface 2d of the second bank layer BN2 facing the non-emission area NLA may be covered by the auxiliary electrode pattern AXp.

The second bank layer BN2 according to some embodiments may have an asymmetrical structure in the portion overlapping the emission area EA and the non-emission area NLA. For example, the second bank layer BN2 may have the tip TIP protruding more than the first side surface 1c of the first bank layer BN1 in the portion overlapping the emission area EA. For this reason, the second bank layer BN2 may have the first side surface 2c protruding more than the first side surface 1c of the first bank layer BN1. In contrast, the second bank layer BN2 may not include a portion protruding more than the second side surface 1d of the first bank layer BN1 in the portion overlapping the non-emission area NLA, and the second side surface 2d of the second bank layer BN2 may be positioned on the same line as the second side surface 1d of the first bank layer BN1.

The bank structure BN according to some embodiments may perform a plurality of functions by having the asymmetrical structure in the portion overlapping the emission area EA and the non-emission area NLA. For example, the bank structure BN may include the tip TIP protruding toward the emission area EA, and accordingly, the first light emitting element ED1, the second light emitting element ED2, and the third light emitting element ED3 respectively positioned in the first emission area EA1, the second emission area EA2, and the third emission area EA3 so as to be spaced apart from each other may be formed. In addition, the bank structure BN may solve a reliability defect caused by moisture included in the via layer VIA in the fabricating process by exposing the third opening OP3 in the portion overlapping the non-emission area NLA.

In the portion overlapping the non-emission area NLA, the first element inorganic layer IO1, the element inorganic pattern IOp, and the second element inorganic layer IO2 may be spaced apart from each other. In addition, the second element inorganic layer IO2, the element inorganic pattern IOp, and the third element inorganic layer IO3 may also be spaced apart from each other.

In the portion overlapping the non-emission area NLA, the element inorganic pattern IOp may be in contact with and cover the electrode pattern CP, the pixel defining layer PDL, and the first bank layer BN1. It has been illustrated in FIG. 7 that the element inorganic pattern IOp is not in contact with the second bank layer BN2, but the present disclosure is not limited thereto. According to some embodiments, the element inorganic pattern IOp may also be in contact with the second side surface 2d of the second bank layer BN2 facing the third opening OP3.

In the portion overlapping the non-emission area NLA, the first auxiliary electrode AX1, the auxiliary electrode pattern AXp, and the second auxiliary electrode AX2 may be spaced apart from each other. In addition, the second auxiliary electrode AX2, the auxiliary electrode pattern AXp, and the third auxiliary electrode AX3 may also be spaced apart from each other.

The auxiliary electrode pattern AXp may extend from a portion in contact with the element inorganic pattern IOp and be positioned to be in contact with the second bank layer BN2. The auxiliary electrode pattern AXp may also be positioned inside the cavity Cavity positioned between the second bank layer BN2 and the element inorganic layer IO.

The display device 10 according to some embodiments includes the auxiliary electrode pattern AXp, and accordingly, the first cathode electrode CE1, the second cathode electrode CE2, and the third cathode electrode CE3 respectively positioned in portions overlapping the first emission area EA1, the second emission area EA2, and the third emission area EA3 may be electrically connected to each other. For example, the first cathode electrode CE1 may be electrically connected to the second cathode electrode CE2 through the first bank layer BN1, the second bank layer BN2, and the auxiliary electrode pattern AXp positioned between the first emission area EA1 and the second emission area EA2, and the second cathode electrode CE2 may be electrically connected to the third cathode electrode CE3 through the first bank layer BN1, the second bank layer BN2, and the auxiliary electrode pattern AXp positioned between the second emission area EA2 and the third emission area EA3.

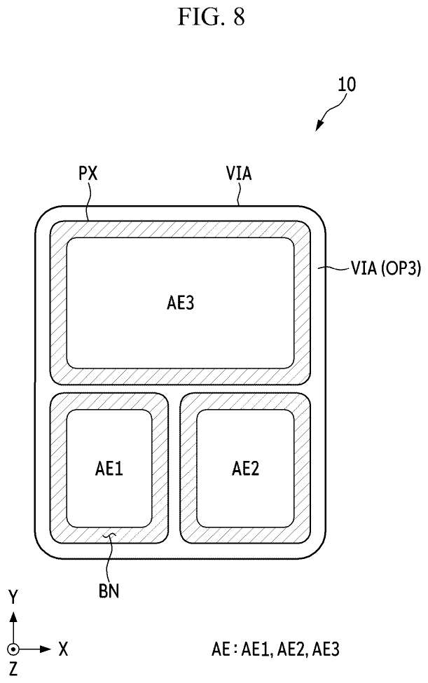

FIG. 8 is a plan view illustrating an arrangement relationship of a via layer, an anode electrode, and a bank structure in FIG. 5. FIG. 8 illustrates the arrangement relationship of the via layer, the anode electrode and the bank structure at an intermediate step of a fabricating process.

Referring to FIG. 8, in a plan view, the bank structure BN may entirely surround an edge of the anode electrode AE, and may expose the via layer VIA in a portion overlapping the third opening OP3.

In the display device 10 according to some embodiments, the via layer VIA positioned at an outer side of each pixel PX is formed to be exposed in the fabricating process, and it is thus possible to solve a reliability defect of the pixel PX caused by moisture included in the via layer VIA. The fabricating process will be described later.

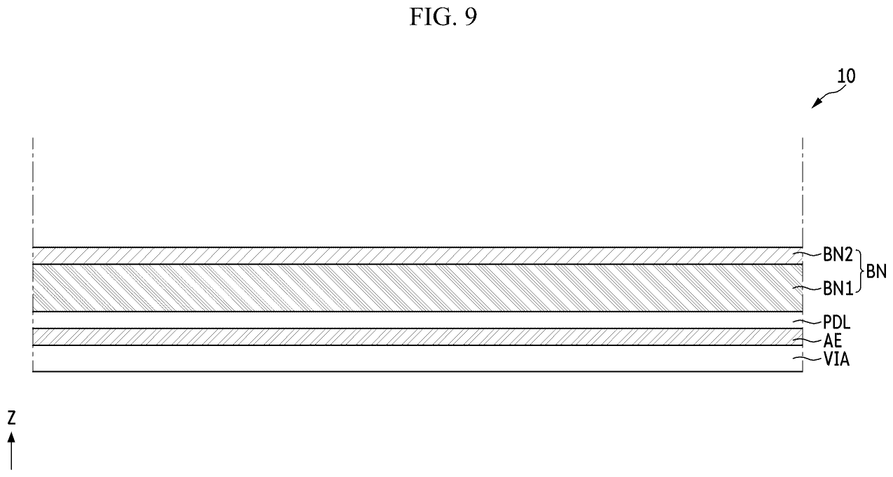

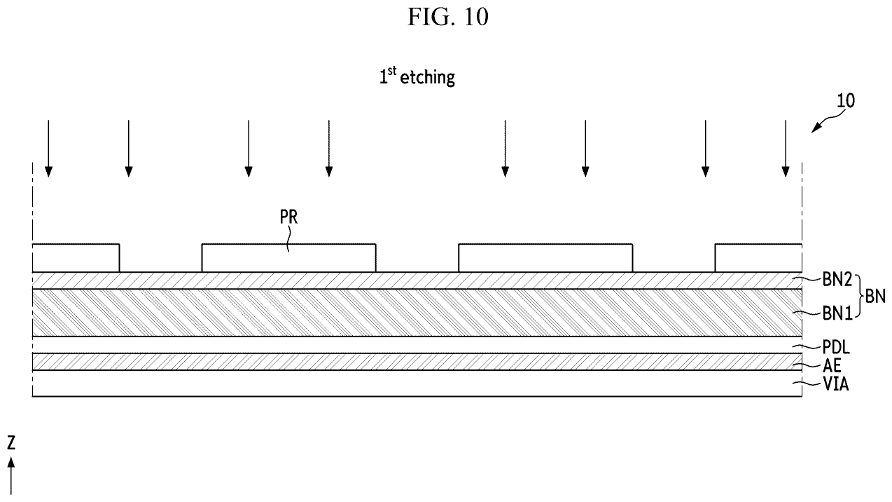

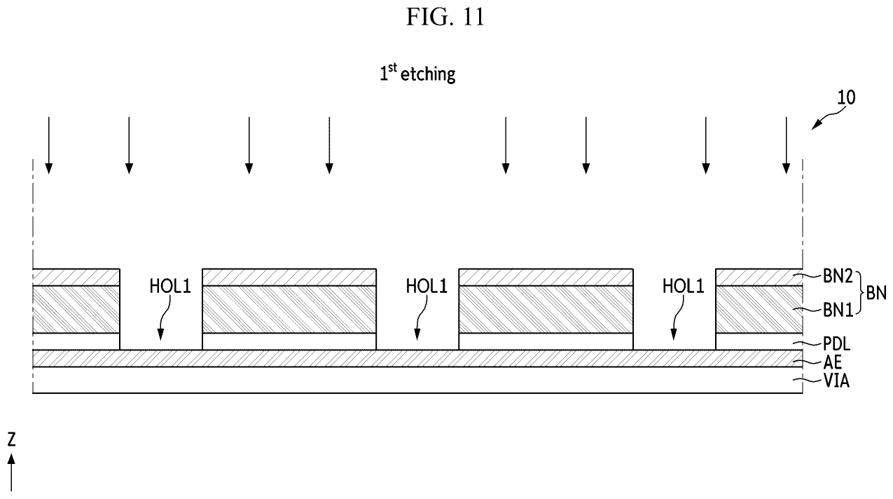

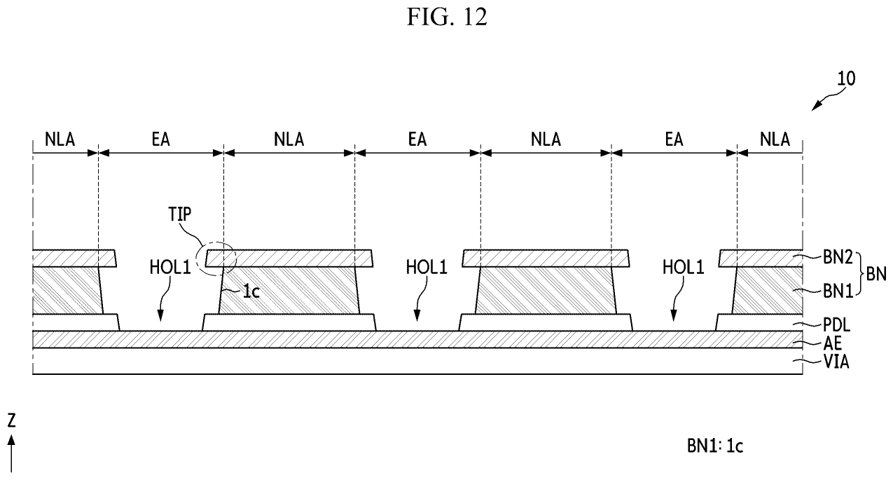

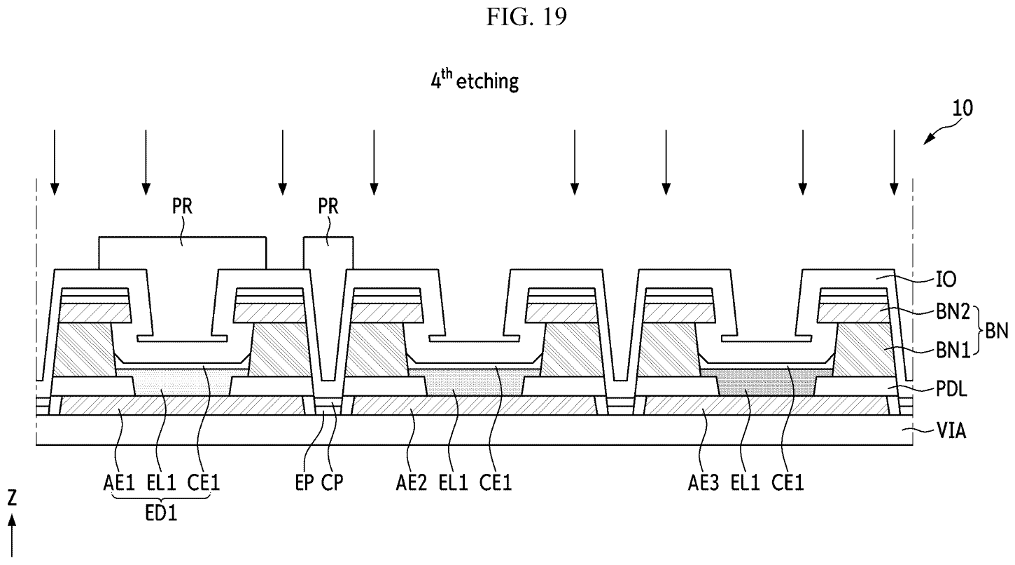

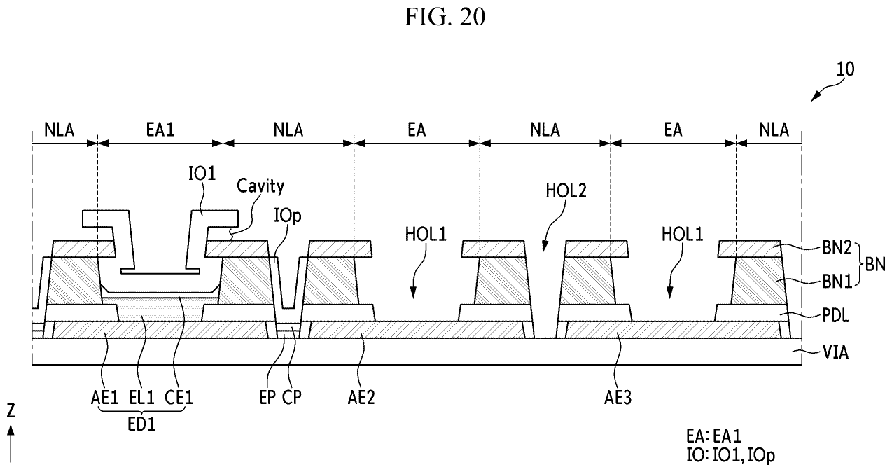

FIGS. 9 to 22 are schematic cross-sectional views illustrating a method for fabrication of the display element layer illustrated in FIG. 5.

Referring to FIGS. 9 to 12, after the anode electrode AE is entirely formed on the via layer VIA, the pixel defining layer PDL and the bank structure BN are entirely formed. The bank structure BNS may include the first bank layer BN1 and the second bank layer BN2 that include different materials and are sequentially stacked. The via layer VIA according to some embodiments may include the organic material described above. A description of overlapping contents is omitted.

Next, a plurality of photoresists PR are formed on the second bank layer BN2. The plurality of photoresists PR may be spaced apart from each other. Subsequently, a first etching process (1^{st} etching) is performed using the plurality of photoresists PR as a mask.

According to some embodiments, in the first etching process (1^{st} etching), a wet etching process and a dry etching process may be alternately performed.

For example, the dry etching process is first performed to isotropically remove portions of the first bank layer BN1, the second bank layer BN2, and the pixel defining layer PDL that do not overlap the plurality of photoresists PR.

In the present process, first holes HOL1 may be formed, and the anode electrode AE overlapping the first holes HOL1 may be exposed. In the present process, one surfaces of the first bank layer BN1, the second bank layer BN2, and the pixel defining layer PDL facing the first hole HOL1 may be positioned on the same line. The first hole HOL1 may be formed in a portion overlapping the emission area EA illustrated in FIG. 5.

Next, the wet etching process is performed to anisotropically remove portions of the first bank layer BN1 and the second bank layer BN2 that do not overlap the plurality of photoresists PR. In the present process, the first bank layer BN1 and the second bank layer BN2 including the different materials may have different etching selectivities. In other words, an etch rate of the first bank layer BN1 may be higher than an etch rate of the second bank layer BN2 with respect to the same etchant. Accordingly, the second bank layer BN2 may include a tip TIP protruding toward the first hole HOL1 more than the first side surface 1c of the first bank layer BN1.

In the present process, the emission area EA and the non-emission area NLA may be defined by openings formed by the pixel defining layer PDL and the bank structure BN.

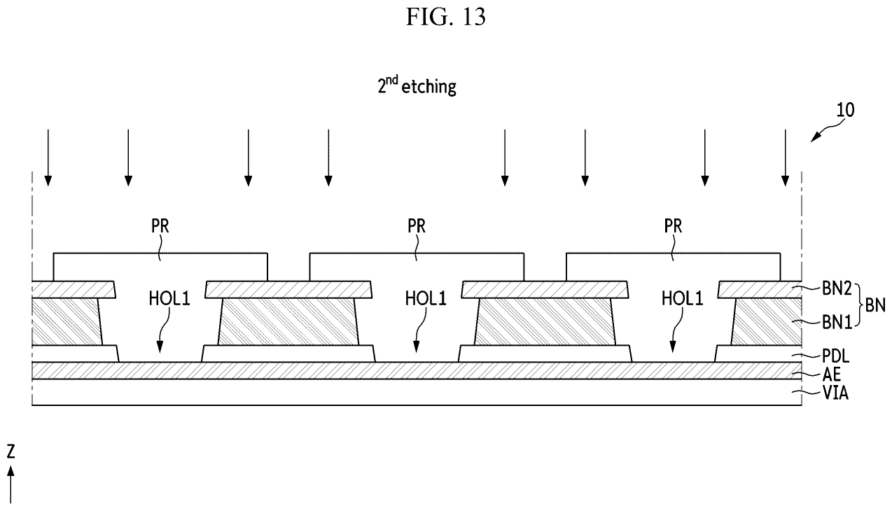

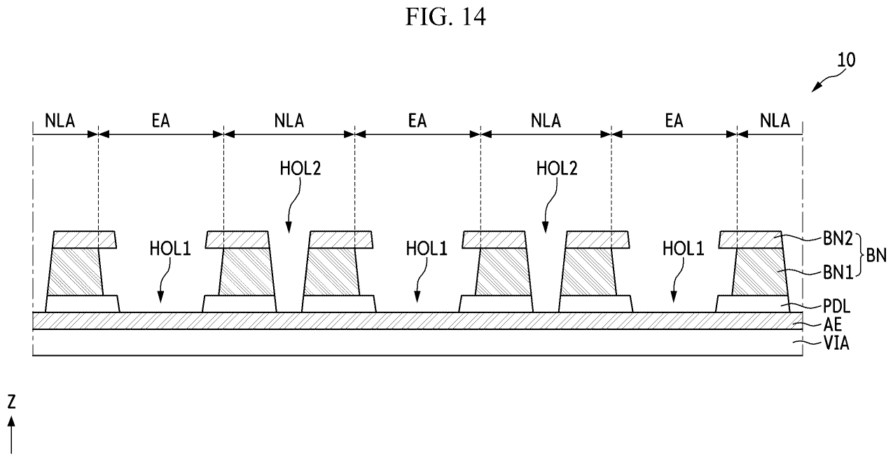

Next, referring to FIGS. 13 and 14, photoresists PR are formed on the second bank layer BN2 so as to cover a plurality of first holes HOL1. In the present process, a plurality of photoresists PR may be spaced apart from each other while exposing central portions of the second bank layer BN2. Subsequently, a second etching process (2^{nd} etching) is performed using the plurality of photoresists PR as a mask. As an example, a dry etching process may be performed as the second etching process (2^{nd} etching).

In the present process, portions of the first bank layer BN1, the second bank layer BN2, and the pixel defining layer PDL that do not overlap the plurality of photoresists PR may be removed. For this reason, second holes HOL2 may be formed. The first hole HOL1 may be positioned to overlap the emission area EA, and the second hole HOL2 may be formed in a portion overlapping the non-emission area NLA.

In the present process, the first bank layer BN1, the second bank layer BN2, and the pixel defining layer PDL facing the second hole HOL2 may be isotropically removed. For this reason, one surfaces of the first bank layer BN1, the second bank layer BN2, and the pixel defining layer PDL facing the second hole HOL2 may be positioned on the same line.

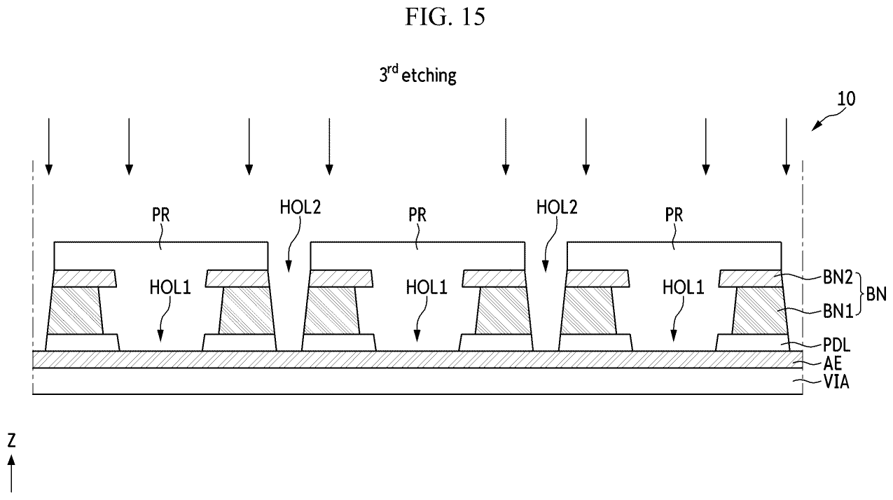

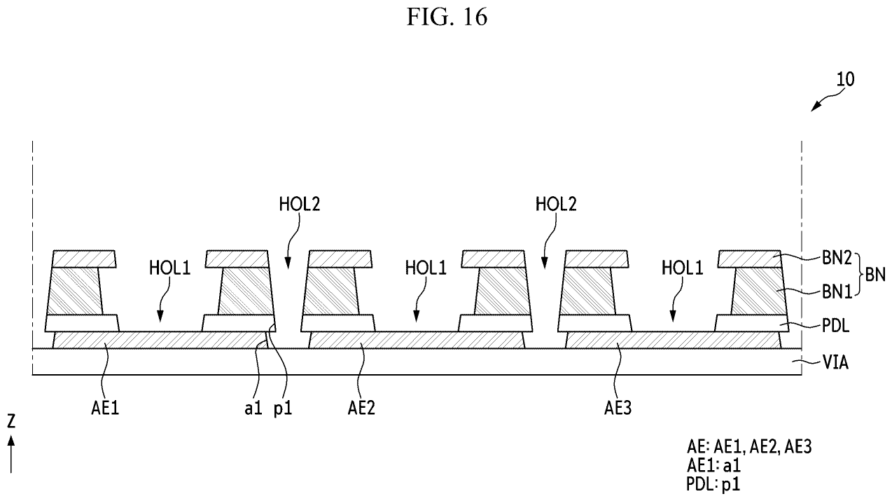

Subsequently, referring to FIGS. 15 and 16, photoresists PR are formed on the second bank layer BN2 so as to cover the plurality of first holes HOL1. In the present process, the plurality of photoresists PR may be spaced apart from each other while exposing the second holes HOL2. Subsequently, a third etching process (3^{rd} etching) is performed using the plurality of photoresists PR as a mask. As an example, a wet etching process may be performed as the third etching process (3^{rd} etching). An etching solution used in the present process may be a non-phosphoric acid etching solution.

In the present process, portions of the anode electrode AE that do not overlap the plurality of photoresists PR may be removed. In other words, in the present process, portions of the anode electrode AE positioned to overlap the second holes HOL2 may be removed.

In the present process, an etch rate of the anode electrode AE may be higher than an etch rates of the bank structure BN and the pixel defining layer PDL with respect to the same etchant. Accordingly, the side surface a1 of the anode electrode AE (e.g., the first anode electrode AE1) positioned in a direction toward the second hole HOL2 may be depressed in a direction toward the first hole HOL1 more than the side surface p1 of the pixel defining layer PDL positioned in the direction toward the second hole HOL2.

In other words, the pixel defining layer PDL may protrude more than the side surface a1 of the anode electrode AE (e.g., the first anode electrode AE1) in the direction toward the second hole HOL2. For this reason, the anode electrode AE and the pixel defining layer PDL may form an undercut shape in the direction toward the second hole HOL2.

In the present process, the via layer VIA may be exposed without being covered by the anode electrode AE in portions overlapping the second holes HOL2.

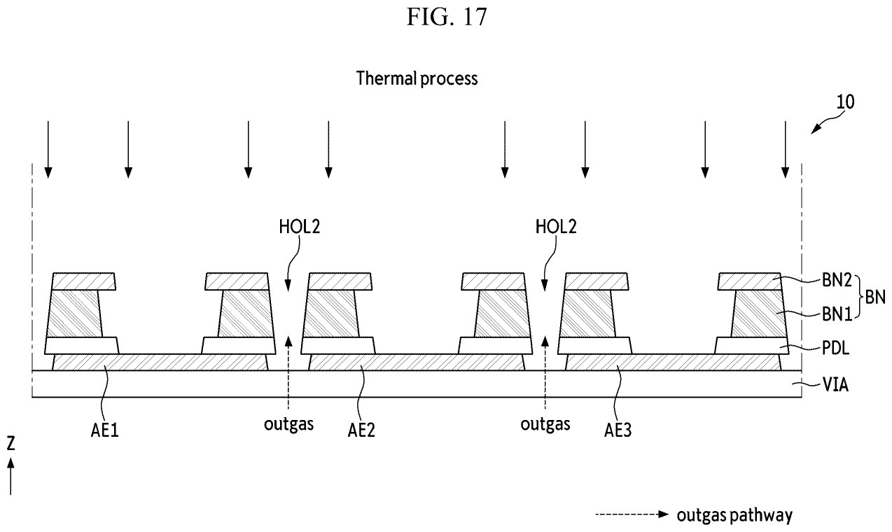

Subsequently, referring to FIG. 17, a thermal process is performed. In the present process, moisture included in the organic material of the via layer VIA may be discharged through an outgas pathway. Accordingly, the display device 10 according to some embodiments may solve a pixel reliability defect caused by an outgas included in the via layer VIA.

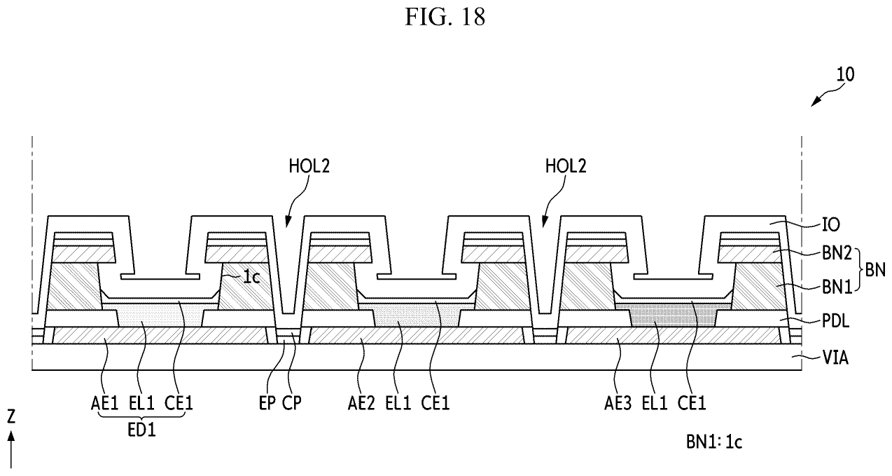

Next, referring to FIGS. 18 to 20, the first light emitting element ED1 is formed by depositing the first light emitting layer EL1, the first cathode electrode CE1, and the first element inorganic layer IO1 on the first anode electrode AE1.

In the present process, the first light emitting layer EL1 may be formed through a thermal deposition process. As an example, the process of forming the first light emitting layer EL1 may be performed without using a separate fine metal mask. For example, the process of forming the first light emitting layer EL1 may be performed at an inclined angle of 45° to 50° with respect to an upper surface of the anode electrode AE.

In the present process, a material forming the first light emitting layer EL1 may be formed not only on the first anode electrode AE1, but also on the second anode electrode AE2, the third anode electrode AE3, the second bank layer BN2, and the via layer VIA overlapping the second hole HOL2. In addition, the material forming the first light emitting layer EL1 may also be formed on the first side surface 1c of the first bank layer BN1. In the present process, the material forming the first light emitting layer EL1, formed on the via layer VIA in a portion overlapping the second hole HOL2 may be formed in the form of the organic pattern EP illustrated in FIG. 5.

In the present process, the first cathode electrode CE1 may be formed through a thermal deposition process or a sputtering deposition process. The process of forming the first cathode electrode CE1 may be performed without a separate fine metal mask, and may have higher step coverage than the deposition process of forming the first light emitting layer EL1. Accordingly, a material forming the first cathode electrode CE1 may entirely cover the material forming the first light emitting layer EL1.

In the present process, the material forming the first cathode electrode CE1 may be formed not only on the first anode electrode AE1, but also on the second anode electrode AE2, the third anode electrode AE3, the second bank layer BN2, and the via layer VIA overlapping the second hole HOL2. In addition, the material forming the first cathode electrode CE1 may also be formed on the first side surface 1c of the first bank layer BN1. In the present process, the material forming the first cathode electrode CE1, formed on the via layer VIA in the portion overlapping the second hole HOL2 may be formed in the form of the electrode pattern CP illustrated in FIG. 5.

Next, the element inorganic layer IO is formed on the first light emitting element ED1. The element inorganic layer IO may be entirely formed. For example, a material forming the element inorganic layer IO may be formed not only on the first light emitting element ED1, but also on the second anode electrode AE2, the third anode electrode AE3, the second bank layer BN2, and the electrode pattern CP.

Next, photoresists PR are formed on the element inorganic layer IO in a portion overlapping the first light emitting element ED1 and a portion overlapping the electrode pattern CP positioned around the first light emitting element ED1. Subsequently, a fourth etching process (4^{th} etching) is performed using the plurality of photoresists PR as a mask. As an example, in the fourth etching process (4^{th} etching), a wet etching process and a dry etching process may be alternately performed.

In the present process, the material forming the first light emitting layer EL1, the material forming the first cathode electrode CE1, and the material forming the element inorganic layer IO that do not overlap the photoresists PR may be removed at a time.

In the present process, the element inorganic layer IO may be formed in the form of the first element inorganic layer IO1 and the element inorganic pattern IOp, and the first element inorganic layer IO1 and the element inorganic pattern IOp may be spaced apart from each other. The first element inorganic layer IO1 may entirely cover the first light emitting element ED1, and the element inorganic pattern IOp may entirely cover the electrode pattern CP.

In the present process, the emission area EA where the first light emitting element ED1 is positioned may be defined as the first emission area EA1. In other words, the first element inorganic layer IO1 may be positioned in a portion overlapping the first emission area EA1, and the element inorganic pattern IOp may be positioned in a portion overlapping the non-emission area NLA.

In the present process, the first element inorganic layer IO1 and the second bank layer BN2 may be spaced apart from each other in the third direction (Z-axis direction) with the cavity Cavity interposed therebetween. The cavity Cavity may be formed by removing the material forming the first light emitting layer EL1 and the material forming the first cathode electrode CE1 that are temporarily positioned on the second bank layer BN2.

In the present process, first holes HOL1 may be formed again in portions overlapping the second anode electrode AE2 and the third anode electrode AE3, and a second hole HOL2 may be formed in a portion overlapping a portion between the second anode electrode AE2 and the third anode electrode AE3.

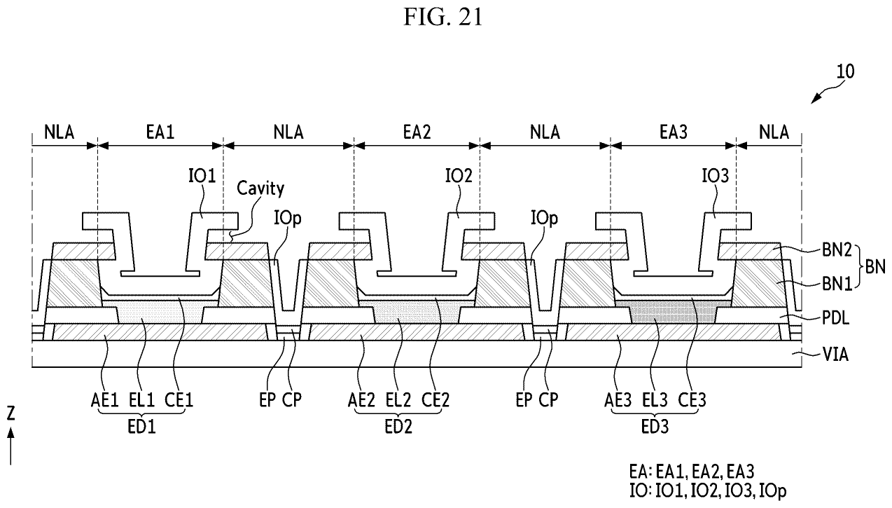

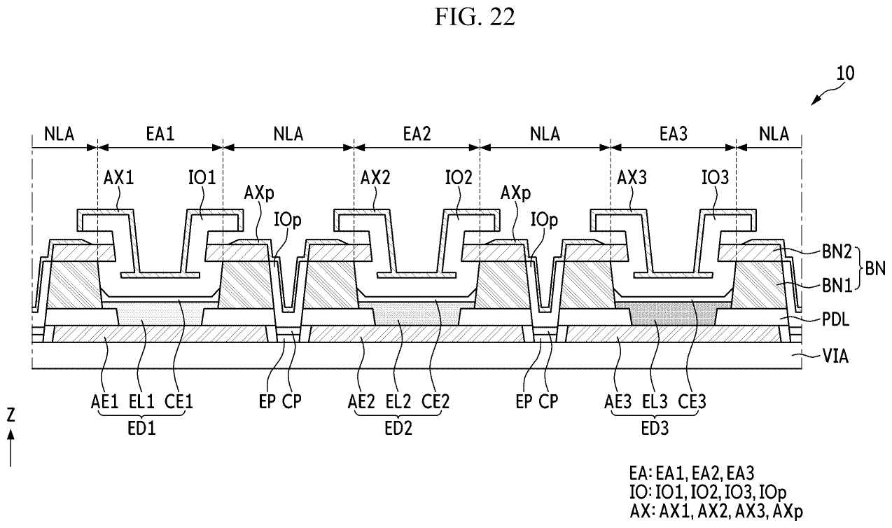

Next, referring to FIGS. 21 and 22, the second light emitting element ED2 and the second element inorganic layer IO2 covering the second light emitting element ED2 are formed by repeating the same process as the process described above, and the third light emitting element ED3 and the third element inorganic layer IO3 covering the third light emitting element ED3 are formed by repeating the same process as the process described above again.

The first element inorganic layer IO1, the second element inorganic layer IO2, and the third element inorganic layer IO3 may be spaced apart from each other with the element inorganic pattern IOp interposed therebetween, and may be spaced apart from the second bank layer BN2 in the third direction (Z-axis direction) with the cavity Cavity interposed therebetween.

In the present process, the emission area EA where the second light emitting element ED2 is positioned may be defined as the second emission area EA2, and the emission area EA where the third light emitting element ED3 is positioned may be defined as the third emission area EA3.

Next, the auxiliary electrode AX is formed on the element inorganic layer IO. In the present process, the auxiliary electrode AX may be formed through a thermal deposition process or a sputtering deposition process. The auxiliary electrode AX may be entirely deposited without using a separate fine metal mask.

In the present process, the auxiliary electrode AX may cover an underlying structure at a uniform thickness along a step of the underlying structure. For this reason, the auxiliary electrodes AX may be formed on the first element inorganic layer IO1, the second element inorganic layer IO2, the third element inorganic layer IO3, and the element inorganic pattern IOp so as to be spaced apart from each other without a separate fine metal mask.

As an example, the auxiliary electrode AX may include the first auxiliary electrode AX1 formed on the first element inorganic layer IO1, the second auxiliary electrode AX2 formed on the second element inorganic layer IO2, the third auxiliary electrode AX3 formed on the third element inorganic layer IO3, and the auxiliary electrode pattern AXp formed on the element inorganic pattern IOp. Consequently, the display element layer illustrated in FIG. 5 may be formed.

The display device according to one embodiment of the present disclosure can be applied to various electronic devices. The electronic device according to the one embodiment of the present disclosure includes the display device described above, and may further include modules or devices having additional functions in addition to the display device.

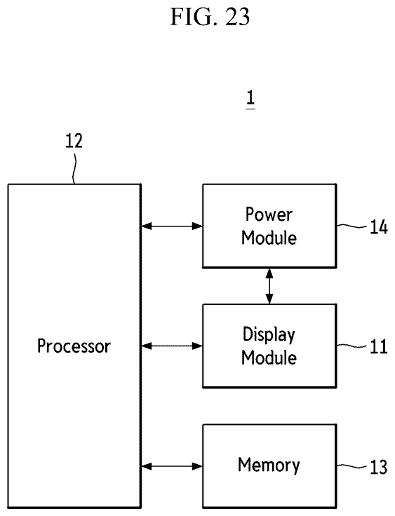

FIG. 23 is a block diagram of an electronic device according to one embodiment of the present disclosure.

Referring to FIG. 23, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

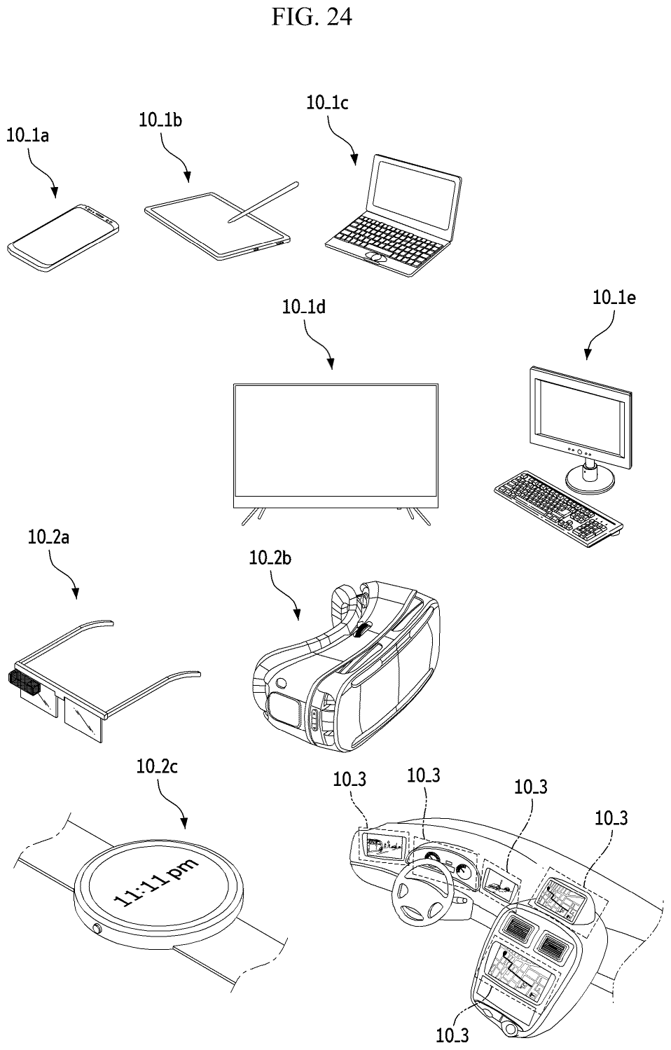

FIG. 24 is a schematic diagram of an electronic device according to various embodiments of the present disclosure.

Referring to FIG. 24, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate including an emission area and a non-emission area;
a via layer on the substrate;
an anode electrode overlapping the emission area and on the via layer;
a pixel defining layer on the anode electrode and defining a first opening; and
a bank structure on the pixel defining layer and defining a second opening,
wherein the pixel defining layer and the bank structure surround a third opening in a portion overlapping the non-emission area, and
the third opening does not overlap the anode electrode in the portion overlapping the non-emission area.

2. The display device of claim 1, further comprising:
a light emitting layer on the anode electrode and contacting the bank structure;
a cathode electrode on the light emitting layer and contacting the bank structure;
an element inorganic layer on the cathode electrode; and
an auxiliary electrode on the element inorganic layer.

3. The display device of claim 2, wherein the bank structure includes a first bank layer and a second bank layer having different metal materials, and
the second bank layer includes a tip protruding toward the first opening more than a first side surface of the first bank layer facing the emission area.

4. The display device of claim 3, wherein in a portion overlapping the emission area, the element inorganic layer contacts and covers the first side surface of the first bank layer and the tip of the second bank layer.

5. The display device of claim 3, wherein in a portion overlapping the emission area, the second bank layer and the element inorganic layer are spaced apart from each other in a direction perpendicular to the substrate with a cavity interposed therebetween.

6. The display device of claim 5, further comprising an organic encapsulation layer on the auxiliary electrode,
wherein the organic encapsulation layer fills the cavity.

7. The display device of claim 1, wherein in a plan view, the first opening is entirely surrounded by the second opening.

8. The display device of claim 3, wherein the element inorganic layer includes a first element inorganic layer overlapping the emission area and an element inorganic pattern overlapping the non-emission area, and
the first element inorganic layer and the element inorganic pattern are spaced apart from each other.

9. The display device of claim 8, wherein in a portion overlapping the third opening, the via layer is exposed, and
in the portion overlapping the third opening, the element inorganic pattern entirely covers the via layer.

10. The display device of claim 8, wherein the element inorganic pattern contacts and covers a second side surface of the first bank layer facing the third opening.

11. The display device of claim 1, wherein in the portion overlapping the non-emission area, a side surface of the pixel defining layer facing the third opening protrudes toward the third opening more than a side surface of the anode electrode facing the third opening.

12. The display device of claim 11, wherein in the portion overlapping the non-emission area, the pixel defining layer and the side surface of the anode electrode facing the third opening form an undercut.

13. The display device of claim 8, wherein the auxiliary electrode includes a first auxiliary electrode on the first element inorganic layer and an auxiliary electrode pattern positioned on the element inorganic pattern, and
the first auxiliary electrode and the auxiliary electrode pattern are spaced apart from each other.

14. The display device of claim 13, wherein the cathode electrode is electrically connected to the auxiliary electrode pattern through the bank structure.

15. The display device of claim 13, wherein the auxiliary electrode pattern contacts the second bank layer.

16. The display device of claim 2, further comprising an electrode pattern on the via layer so as to overlap the third opening,
wherein the electrode pattern includes a same material as the cathode electrode, and
in the portion overlapping the non-emission area, the anode electrode is spaced apart from the electrode pattern with a space interposed therebetween.

17. A method for fabrication of a display device, comprising:
forming a substrate including an emission area and a non-emission area and forming a via layer on the substrate;
entirely forming an anode electrode on the via layer and sequentially forming a pixel defining layer and a bank structure on the anode electrode;
forming a first hole and a second hole by removing portions of the bank structure and the pixel defining layer, the first hole overlapping the emission area and the second hole overlapping the non-emission area;
exposing the via layer overlapping the second hole by removing a portion of the anode electrode overlapping the second hole;
removing moisture included in the via layer by performing a thermal process; and
forming a light emitting layer, a cathode electrode, an inorganic element layer, and an auxiliary electrode on the anode electrode.

18. The method for fabrication of a display device of claim 17, wherein in the forming of the first hole, the bank structure includes a tip protruding toward the first hole.

19. The method for fabrication of a display device of claim 18, wherein in the forming of the light emitting layer and the cathode electrode, the light emitting layer and the cathode electrode are formed by a deposition process and an etching process without a separate mask.

20. An electronic device comprising:
a display panel including a substrate including a display area including an emission area and a non-emission area and a non-display area surrounding an outer side of the display area,
wherein the display panel further includes:
a via layer on the substrate;
an anode electrode overlapping the emission area and on the via layer;
a pixel defining layer on the anode electrode and defining a first opening; and
a bank structure on the pixel defining layer and defining a second opening,
the pixel defining layer and the bank structure surround a third opening in a portion overlapping the non-emission area, and
the third opening does not overlap the anode electrode in the portion overlapping the non-emission area.
